(19) United States
(12) Patent Application Publication
(10) Pub. No.: US 2026/0302602 A1
(43) Pub. Date: Oct. 1, 2026

(54) RADIO FREQUENCY ADJUSTMENT STRUCTURE REDUCING INFLUENCE OF METAL DEBRIS

(71) Applicant: Suzhou Luxshare Technology Co., Ltd., Suzhou City (CN)

(72) Inventors: Zhen-guo SONG, Suzhou City (CN); Shao-dong LI, Suzhou City (CN); Xu LIU, Suzhou City (CN); Xing-liao NING, Suzhou City (CN)

(73) Assignee: Suzhou Luxshare Technology Co., Ltd., Suzhou City (CN)

(21) Appl. No.: 19/367,125

(22) Filed: Oct. 23, 2025

(30) Foreign Application Priority Data
Mar. 31, 2025 (CN) 202510390124.3

(51) Int. Cl. H01Q 1/42; H01Q 3/02

(52) U.S. Cl. CPC H01Q 1/42; H01Q 3/02

(57) ABSTRACT

A radio frequency adjustment structure includes a box base, a cover plate, an adjustable screw rod and a debris collector. The cover plate covers the box base to define a functional cavity between the cover plate and the box base. The cover plate includes a top surface facing away from the functional cavity and a bottom surface facing the functional cavity for defining a vertical direction. The cover plate defines a through hole which communicates the top surface with the bottom surface along the vertical direction. The adjustable screw rod is positioned to the cover plate, penetrates through the through hole and partially extends into the functional cavity. The debris collector is arranged beneath the bottom surface of the cover plate and corresponds to a location of the through hole.

### CROSS-REFERENCE TO RELATED APPLICATION

This patent application claims priority of a Chinese Patent Application No. 202510390124.3, filed on Mar. 31, 2025 and titled “RADIO FREQUENCY ADJUSTMENT STRUCTURE”, the entire content of which is incorporated herein by reference.

### TECHNICAL FIELD

The present disclosure relates to a field of radio frequency, particularly to a radio frequency adjustment structure reducing influence of metal debris.

### BACKGROUND

In an existing radio frequency (RF) adjustment structure in a RF field, either two components of an adjustable screw and a cover plate, or another two components of the adjustable screw and a screw nut secured on the cover plate, are combined through some internal and external threads, allowing the adjustable screw to penetrate through the cover plate and therefore suspended on the cover plate. Frequency is adjusted by varying a depth of the adjustable screw partly inserted below the cover plate. During a RF adjustment process, friction maybe be generated between two metal parts of the adjustable screw and the cover plate, or, friction maybe be generated between three metal parts of the adjustable screw, the cover plate and the screw nut. Debris (metal wires and metal powder) usually occurs under the friction. Debris is carried into a functional cavity (also called as a frequency adjustment cavity) by the internal threads and the external threads, which easily causes a short circuit between the adjustable screw and a resonant rod, or even causes poor intermodulation. Therefore, it is necessary to remove the cover plate for cleaning. After cleaning, a second adjustment is needed, and debris (metal wires and metal powder) will be produced during the second adjustment again. The existing radio frequency (RF) adjustment structure requires two or more times of removing and cleaning the cover plate, resulting in high manufacturing costs and low production pass rates.

### SUMMARY

An embodiment of the present disclosure adopts the following technical solution: a radio frequency adjustment structure, including: a box base; a cover plate covering the box base to define a functional cavity between the cover plate and the box base, the cover plate including a top surface facing away from the functional cavity and a bottom surface facing the functional cavity for defining a vertical direction, the cover plate defining a through hole communicating the top surface with the bottom surface along the vertical direction; an adjustable screw rod being positioned to the cover plate, penetrating through the through hole and partially extending into the functional cavity; and a debris collector being arranged beneath the bottom surface of the cover plate and corresponding to a location of the through hole.

An embodiment of the present disclosure adopts the following technical solution: a radio frequency adjustment structure, including: a cover plate, the cover plate including a top surface and a bottom surface oppositely facing along a vertical direction, the cover plate extending in a horizontal direction perpendicular to the vertical direction, the cover plate defining a through hole communicating the top surface with the bottom surface along the vertical direction; an adjustable screw rod being positioned to the cover plate and penetrating through the through hole by means of partially extending beyond the top surface and partially extending below the bottom surface; and a debris collector being arranged just below the through hole and attached to the cover plate.

### BRIEF DESCRIPTION OF DRAWINGS

FIG. 1 is a perspective, assembled view of a radio frequency (RF) adjustment structure of the present disclosure in accordance with an embodiment of the present disclosure;

FIG. 2 is a top view of the RF adjustment structure in accordance with the embodiment of the present disclosure;

FIG. 3 is a cross-sectional view taken along line A-A in FIG. 2 of the RF adjustment structure under an assembled state in accordance with a first embodiment of the present disclosure;

FIG. 4 is a cross-sectional view of the assembled state of an adjustable screw, a cover plate and a debris collector in the first embodiment of the RF adjustment structure;

FIG. 5 is a cross-sectional view taken along line A-A in FIG. 2 of the RF adjustment structure under an exploded state in accordance with the first embodiment of the present disclosure;

FIG. 6 is a cross-sectional view taken along line A-A in FIG. 2 of the RF adjustment structure under an assembled state in accordance with a second embodiment of the present disclosure;

FIG. 7 is a cross-sectional view of the assembled state of the adjustable screw, the cover plate and the debris collector in the second embodiment of the RF adjustment structure;

FIG. 8 is a cross-sectional view taken along line A-A in FIG. 2 of the RF adjustment structure under an exploded state in accordance with the second embodiment of the present disclosure;

FIG. 9 is a cross-sectional view taken along line A-A in FIG. 2 of the RF adjustment structure under an assembled state in accordance with a third embodiment of the present disclosure;

FIG. 10 is a cross-sectional view of the assembled state of the adjustable screw, the cover plate and the debris collector in the third embodiment of the RF adjustment structure;

FIG. 11 is a cross-sectional view taken along line A-A in FIG. 2 of the RF adjustment structure under an exploded state in accordance with the third embodiment of the present disclosure;

FIG. 12 is a cross-sectional view taken along line A-A in FIG. 2 of the RF adjustment structure under an assembled state in accordance with a fourth embodiment of the present disclosure;

FIG. 13 is a cross-sectional view of the assembled state of the adjustable screw, the cover plate and the debris collector in the fourth embodiment of the RF adjustment structure; and

FIG. 14 is a cross-sectional view taken along line A-A in FIG. 2 of the RF adjustment structure under an exploded state in accordance with the fourth embodiment of the present disclosure.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

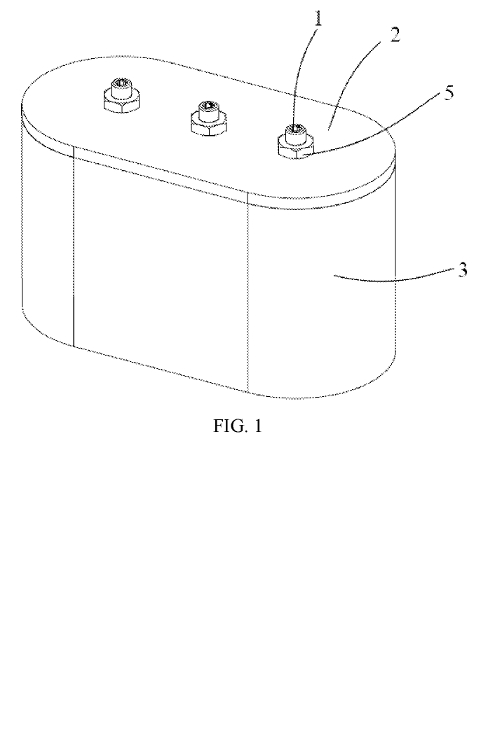

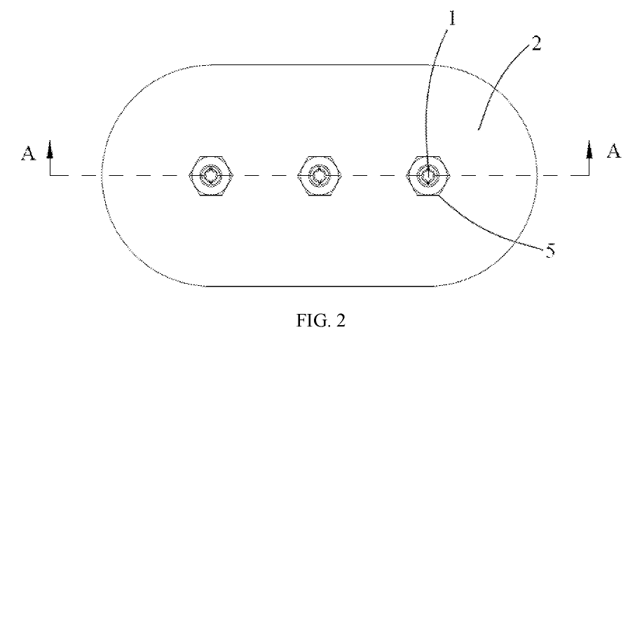

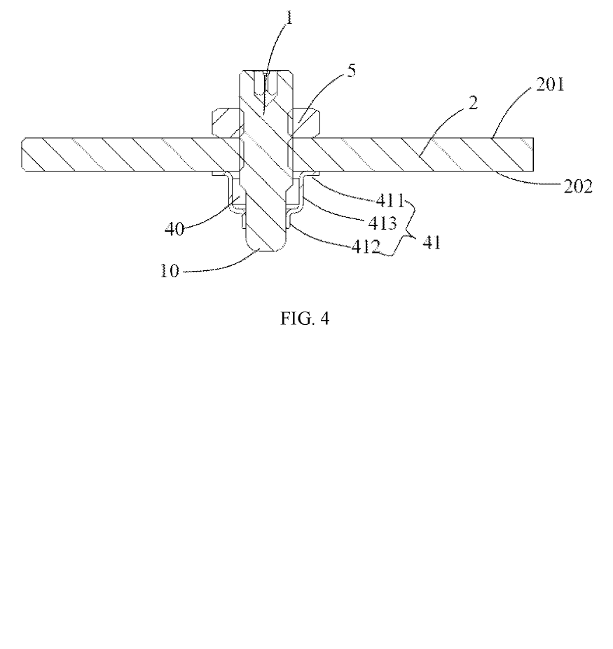

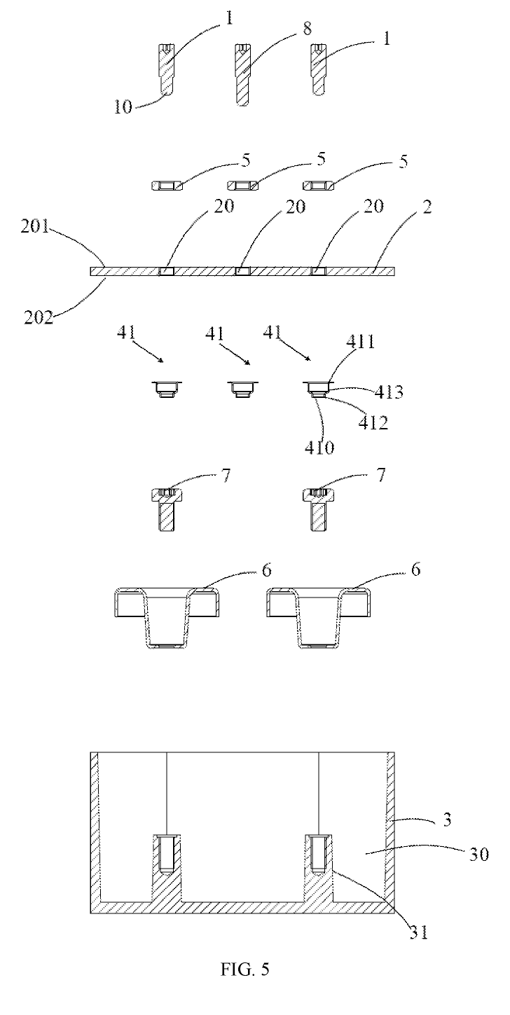

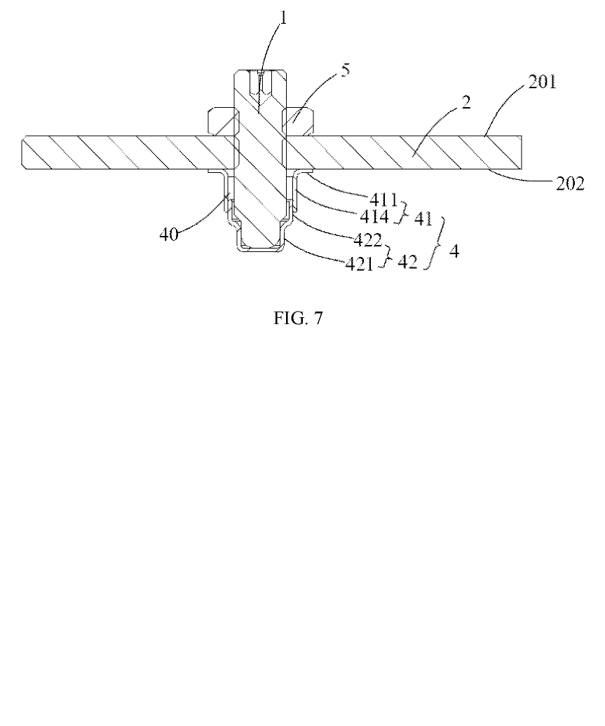

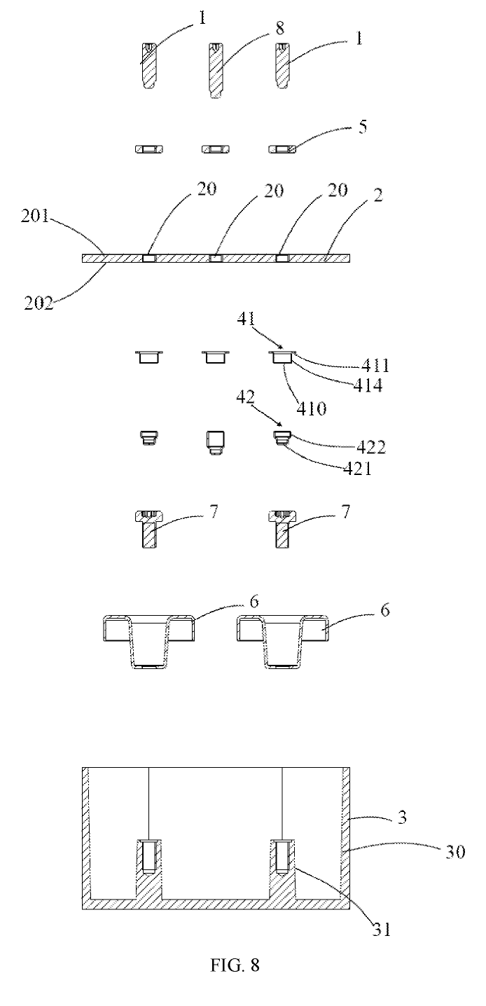

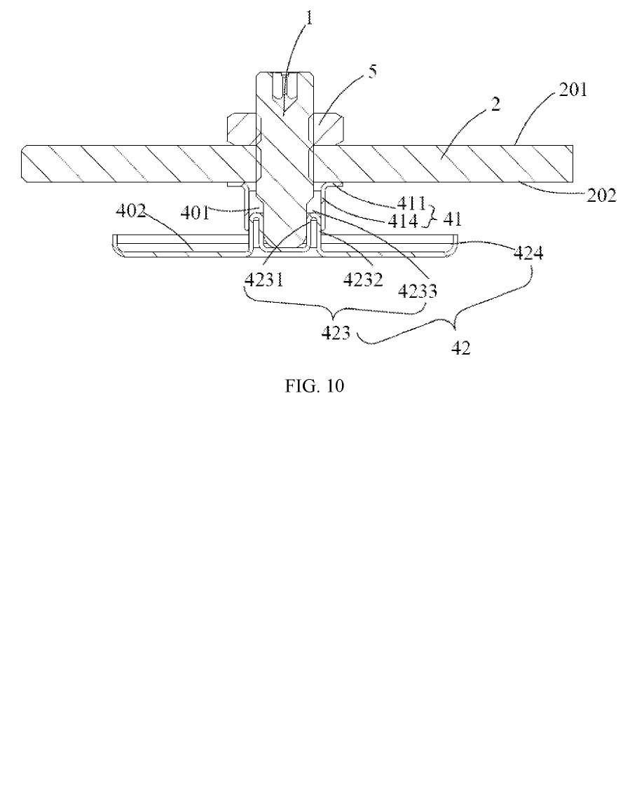

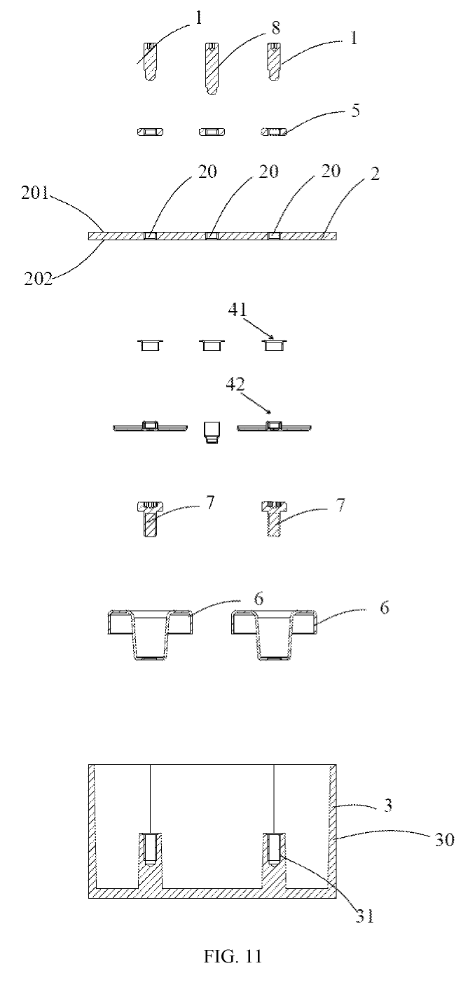

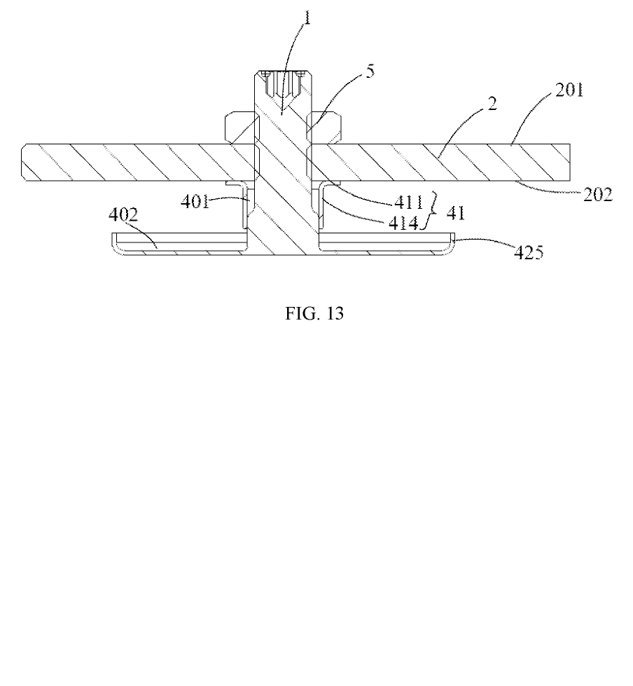

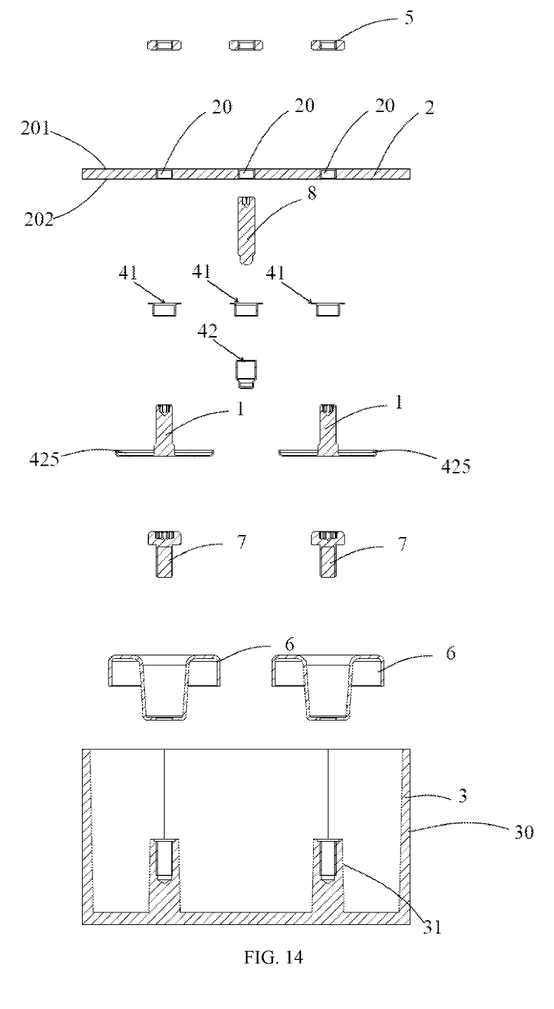

Referring to FIGS. 1-14, the present disclosure discloses a radio frequency (RF) adjustment structure, which includes: an adjustable screw rod 1, a cover plate 2, a box base 3 and a debris collector 4. The cover plate 2 is positioned on a top edge of the box base 3 and a functional cavity 30 is formed between the cover plate 2 and the box base 3. The cover plate 2 includes a top surface 201 facing away from the functional cavity 30 and a bottom surface 202 facing the functional cavity 30. Therefore, a top-bottom direction is defined as a vertical direction and a horizontal direction is perpendicular to the vertical direction. The cover plate 2 extends in the horizontal direction. The cover plate 2 defines a through hole 20 communicating the top surface 201 with the bottom surface 202. The adjustable screw rod 1 is positioned to the cover plate 2 and penetrates through the through hole 20 and partially extends into the functional cavity 30. The debris collector 4 is arranged beneath the bottom surface 202 of the cover plate 2 and corresponds to a location of the through hole 20. Therefore, the radio frequency adjustment structure of the present disclosure includes the debris collector 4 for collecting debris, reducing the possibility of debris falling into the functional cavity 30 below the cover plate 2, and optimizing the frequency adjustment effect.

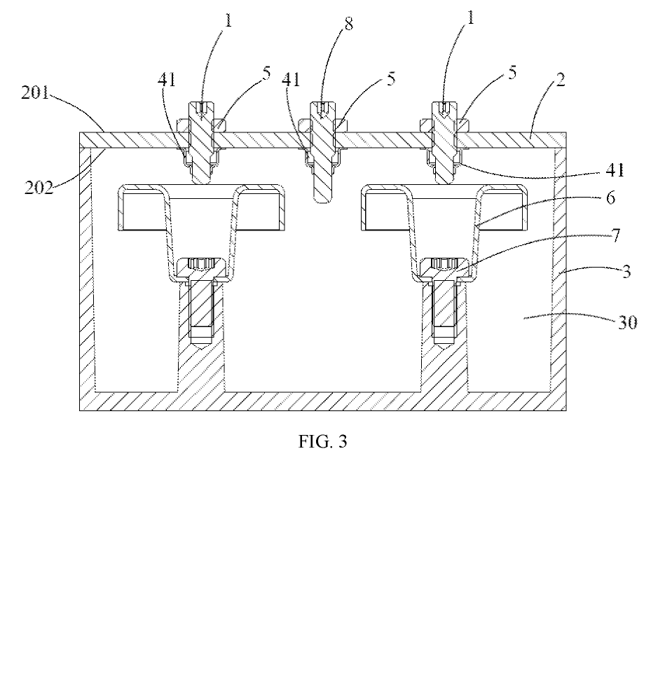

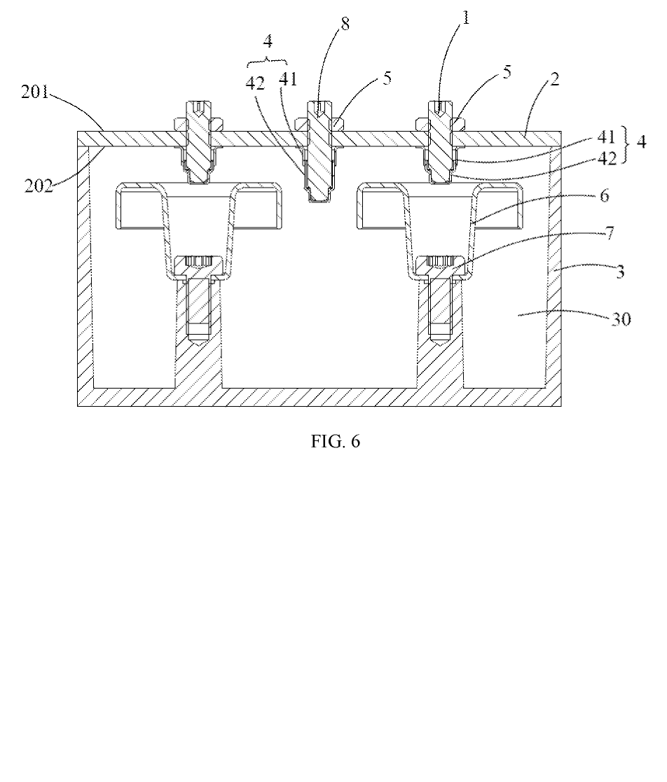

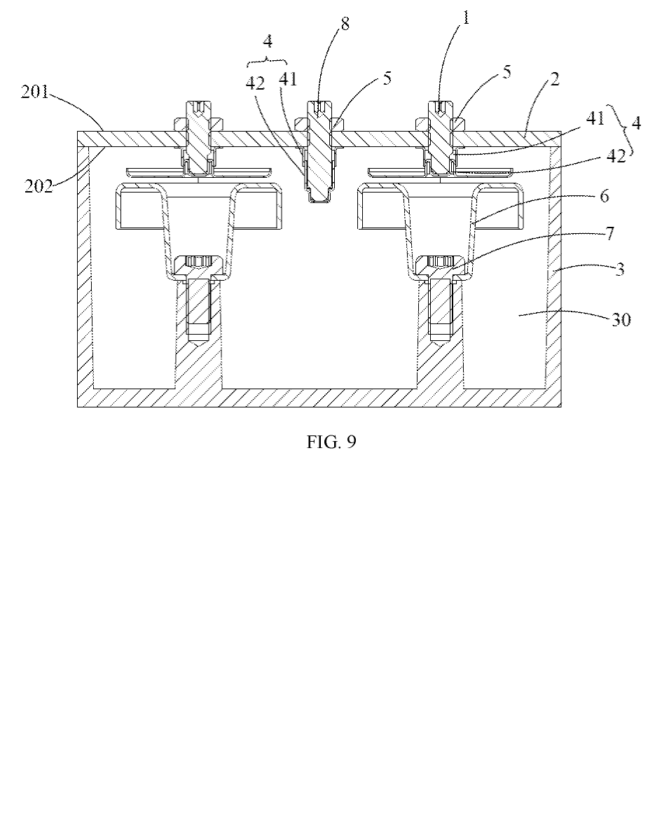

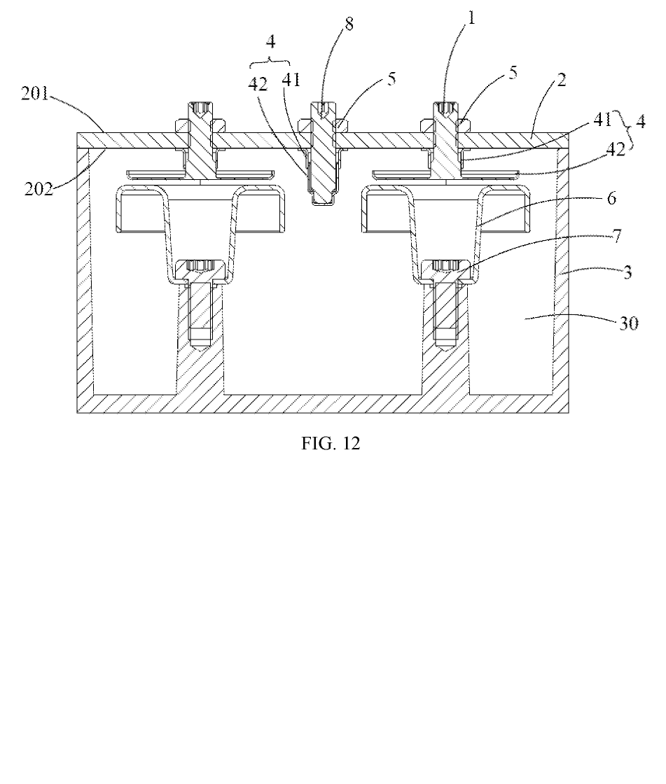

Referring to a first embodiment shown in FIGS. 3-5, a second embodiment shown in FIGS. 6-8, a third embodiment shown in FIGS. 9-11, and a fourth embodiment shown in FIGS. 12-14, the debris collector 4 includes a first component 41. The first component 41 includes a top annular surface 411 extending in the horizontal direction. The top annular surface 411 is fixedly attached to the bottom surface 202 of the cover plate 2 at the location around the through hole 20. The top annular surface 411 of the debris collector 4 is fixedly attached to the bottom surface 202 of the cover plate 2, so that debris can be introduced into the wall surface of the debris collector 4 below the cover plate 2 through the through hole 20 for collection, and will not fall into the functional cavity 30 outside the wall surface of the debris collector 4, optimizing the frequency adjustment effect.

Referring to the first embodiment shown in FIGS. 3-5, the first component 41 includes a bottom annular surface 412 extending in the vertical direction. With respect to the first component 41 alone, the bottom annular surface 412 forms a bottom opening 410 of the first component 41; however, at the location of the bottom opening 410, the inner wall surface of the bottom annular surface 412 in the first embodiment is maintained in contact with the outer wall surface of the adjustable screw rod 1. It should be emphasized that since the top annular surface 411 is fixedly attached to the bottom surface 202 of the cover plate 2 (specifically, it is welded in the implementation mode), although the bottom annular surface 412 is maintained in contact with the outer wall surface of the adjustable screw rod 1, they are not fixedly locked. That is to say, during a frequency adjustment process, there is a relative rotational movement between the adjustable screw rod 1 and the first component 41. The first component 41 in the first embodiment also includes a sidewall annular portion 413 connecting the top annular surface 411 and the bottom annular surface 412. Through the gap between the sidewall annular portion 413 and the adjustable screw rod 1, a cavity 40 for collecting debris can be formed between the sidewall annular portion 413 and the adjustable screw rod 1. Since the inner wall surface of the bottom annular surface 412 and the outer wall surface of the adjustable screw rod 1 are in contact in an ideal state without any gap, although debris can fall into the cavity 40 below the cover plate 2 through the through hole 20, they will not fall into the functional cavity 30, optimizing the frequency adjustment effect. However, since there is a relative rotational movement between the adjustable screw rod 1 and the first component 41, the ideal state of seamless contact is difficult to achieve. In a non-ideal state, a little of debris will still fall into the functional cavity 30 of the radio frequency adjustment structure of the present disclosure. Therefore, inventors of the applicant have further studied the following second and third embodiments as supplements to the first embodiment.

Referring to the second embodiment shown in FIGS. 6-8 and the third embodiment shown in FIGS. 9-11, the first component 41 includes a first annular sidewall 414, which is bent and extended from the inner edge of the top annular surface 411 to form the bottom opening 410 of the first component 41. The significance of the bottom opening 410 herein is to provide the possibility of setting a second component 42 below the first component 41. In the second and third embodiments, the first component 41 no longer serves as the main body for accommodating the debris but becomes a channel for the debris. It should be emphasized that, when adapted to the same adjustable screw rod 1, the diameter of the bottom opening 410 in the second and third embodiments is larger than that in the first embodiment. This is because the collection capacity of the first component 41 in the first embodiment is limited, so the debris collector 4 in both the second embodiment and the third embodiment further includes the second component 42 that is separately positioned below the first component 41 to fill in the bottom opening 410. Therefore, the diameter of the bottom opening 410 in the second and third embodiments needs to be larger (it can be understood that the inner wall surface of the bottom annular surface 412 in the first embodiment does not fit the outer wall surface of the adjustable screw rod 1). In this manner, the second component 42 can be connected below the first component 41. The superposition of the two components (the first component 41 and the second component 42) increases the collection capacity and effect of the debris.

Referring to the second embodiment shown in FIGS. 6-8 and the third embodiment shown in FIGS. 9-11, the bottom opening 410 is blocked by partially inserting the second component 42 into the bottom opening 410. The significance of the insertion and blocking is to make it simple and easy to connect the second component 42 below the first component 41. The superposition of the two components (the first component 41 and the second component 42) also saves vertical space and achieves a better effect of reducing and even preventing debris from leaking out.

Referring to the second embodiment shown in FIGS. 6-8, a bottom of the second component 42 is bowl-shaped. The second component 42 includes a bottom bowl portion 421 and a second annular sidewall 422 that extends integrally upward from the top edge of the bottom bowl portion 421 and is spaced from the adjustable screw rod 1. The adjustable screw rod 1 includes an end portion 10. The bottom bowl portion 421 wraps around the end portion 10. The bottom bowl portion 421 is secured to the end portion 10 by welding in the specific implementation mode. The second annular sidewall 422 is maintained in contact with the first annular sidewall 414 to achieve a connection effect. Therefore, the second component 42 in the second embodiment, except for the bottom bowl portion 421, that is, the second annular sidewall 422 is inserted into the bottom opening 410 to connect the second component 42 below the first component 41. It should be emphasized that the contact between the second annular sidewall 422 and the first annular sidewall 414 in the second embodiment is still a tight fit without any gap in the ideal state. Since the bottom bowl portion 421 wraps around the end portion 10, and in detail, the end portion 10 is welded to the bottom bowl portion 421. Therefore, the second component 42 is firmly secured to the adjustable screw rod 1. During the frequency adjustment process, the adjustable screw rod 1 and the second component 42 are secured with each other and do not move with respect to each other, while the adjustable screw rod 1 and the first component 41 have a relative rotational motion. Therefore, it can be understood that the second component 42 and the first component 41 have a relative rotational motion. The second annular sidewall 422 and the first annular sidewall 414 are in tight contact but not firmly secured with each other. Because the cavity 40 in the second embodiment includes the first cavity 401 formed by the first component 41 and the second cavity 402 formed by the second component 42, the debris can fall from the through hole 20 into the upper first cavity 401 firstly and then into the lower second cavity 402. Gradually, the second cavity 402 will be full of debris and then debris will be filled in the first cavity 401. Due to the tight contact between the second annular sidewall 422 and the first annular sidewall 414 in the ideal state and the existence of the bottom bowl portion 421, the debris will not fall into the functional cavity 30, optimizing the frequency modulation effect. In a non-ideal state, although the second annular sidewall 422 and the first annular sidewall 414 are in tight contact but not fixed, there may still be a small amount of debris falling into the functional cavity 30 of the RF adjustment structure. Therefore, inventors of the applicant have further studied the following third embodiment as a supplement to the second embodiment.

Referring to the third embodiment shown in FIGS. 9-11, a bottom of the second component 42 is plate-shaped. The second component 42 includes an annular protrusion portion 423 at a central thereof and a round plate portion 424 extending outward from a bottom end of the annular protrusion portion 423. The annular protrusion portion 423 includes an inner annular wall 4231, an outer annular wall 4232, and an arc-shaped portion 4233. a top end of the inner annular wall 4231 and a top end of the outer annular wall 4232 are connected by the arc-shaped portion 4233. The round plate portion 424 is coupled to the outer annular wall 4232. Therefore, the round plate portion 424 is a lateral extension of the annular protrusion portion 423 in the radial direction, used for collecting debris over a larger area. The inner annular wall 4231 is maintained in contact with the outer wall surface of the adjustable screw rod 1, and the outer annular wall 4232 is maintained in contact with the inner wall surface of the first annular sidewall 414, achieving the effect of connecting the second component 42 to the bottom of the first component 41, that is, an effect of the connection between the upper and lower parts of the debris collector 4 is achieved. Therefore, the similarities between the third embodiment and the second embodiment are that the adjustable screw rod 1 and the second component 42 are fixed and immovable, so it can be understood that there is a relative rotational movement between the second component 42 and the first component 41. Although the second annular sidewall 422 and the first annular sidewall 414 are in tight contact and ideally seamless, they are not fixed. The difference between the third embodiment and the second embodiment is that in the third embodiment, the annular protrusion portion 423 is inserted into the bottom opening 410 and welded to the end portion 10. Due to the seamless contact between the outer annular wall 4232 and the inner wall surface of the first annular sidewall 414 in the ideal state, the debris will not fall into the functional cavity 30, optimizing the frequency modulation effect. Because there is a relative rotational movement between the second component 42 and the first component 41, even if a small amount of debris may fall from the possible gap between the outer annular wall 4232 and the inner wall surface of the first annular sidewall 414, such debris will fall onto the round plate portion 424 instead of into the functional cavity 30 of the RF adjustment structure.

It can be understood that the specific implementation mode of the bowl shape is by stamping; in other implementation modes, the bowl shape can also be formed by drawing. The specific implementation mode of the disc shape is by drawing; in other implementation modes, the disc shape can also be formed by stamping. That is to say, the entire second component 42 is formed by either stamping or drawing. During the stamping or drawing process of the second component 42, the bottom of the second component 42 is formed into either a bowl shape or a disc shape.

Based on the third embodiment, inventors of the applicant have further developed the following fourth embodiment as a variant of the third embodiment.

Referring to the fourth embodiment shown in FIGS. 12-14, the debris collector 4 includes a first component 41 and a second component 42. The first component 41 includes a top annular surface 411 and a first annular sidewall 414 that extends downward from the top annular surface 411. The top annular surface 411 extends laterally and is fixedly attached to the bottom surface 202 of the cover plate 2. The first annular sidewall 414 forms a bottom opening 410 of the first component 41. The bottom opening 410 in the fourth embodiment is the same as that in the second and third embodiments, providing the possibility of setting the second component 42 below the first component 41. The adjustable screw rod 1 includes an end portion 10 extending downward through the bottom opening 410. The second component 42 is a debris-blocking flat portion 425 formed integrally by stamping from the end portion 10, and the debris-blocking flat portion 425 is located below the bottom opening 410. The similarities between the fourth embodiment and the third embodiment are as follows: both have two components, namely the upper first component 41 and the lower second component 42; both the second component 42 in the third embodiment (the round plate portion 424) and the second component 42 in the fourth embodiment (the debris-blocking flat portion 425) have a disk shape; the first component 41 is immovable and the second component 42 can rotate along with the adjustable screw rod 1. The difference between the fourth embodiment and the third embodiment is that in the fourth embodiment, the second component 42 is a debris-blocking flat portion 425 formed integrally by stamping from the end portion 10, and the first component 41 and the second component 42 in the fourth embodiment are not connected. The second component 42 does not insert into the bottom opening 410 of the first component 41. Therefore, after the debris are guided from the through hole 20 to the first component 41, the debris fall downward through the bottom opening 410 and land on the debris-blocking flat portion 425 of the second component 42, but will not fall into the functional cavity 30.

Referring to FIGS. 1-14, the present disclosure also includes a screw nut 5 secured onto the cover plate 2. The adjustable screw rod 1 passes through the screw nut 5 and extends into the through hole 20. The adjustable screw rod 1 includes an external thread and the screw nut 5 includes an internal thread. The adjustable screw rod 1 is adjustably and fixedly coupled to the cover plate 2 through the cooperation of the internal thread and the external thread. In other unillustrated embodiments, the through hole 20 includes an internal thread and the adjustable screw rod 1 includes an external thread. The adjustable screw rod 1 is adjustably and fixedly coupled to the cover plate 2 through the cooperation of the internal thread and the external thread.

Through the above two methods, the adjustable screw rod 1 can be positioned on the cover plate 2 and its depth can be adjusted through the thread engagement. Therefore, during the thread engagement and screwing process of the two metal parts (namely the adjustable screw rod 1 and the cover plate 2) or the three metal parts (namely the adjustable screw rod 1, the cover plate 2, and the screw nut 5), friction occurs, generating metal wires and metal powder debris and other debris. The present disclosure adds a debris collector 4, which is arranged beneath the bottom surface 202 of the cover plate 2 and corresponds to the location of the through hole 20, to collect the debris that fall from the through hole 20 to the bottom of the cover plate 2, reducing the possibility of debris falling into the functional cavity 30 below the cover plate 2 and optimizing the frequency adjustment effect.

Referring to FIGS. 3-14, the RF adjustment structure also includes a resonant rod 6 located in the functional cavity 30 and secured to the box base 3. The resonant rod 6 is coupled to the upwardly protruding column 31 on the inner bottom surface of the box base 3 by a screw nail 7. The adjustable screw rod 1 is located directly above the resonant rod 6. Therefore, by changing the depth to which the adjustable screw rod 1 extends into the area beneath the cover plate 2, the frequency of the RF adjustment structure can be adjusted.

Referring to FIGS. 3-14, it should also be noted that, the adjustable screw rod 1, in addition to some ones directly above the resonant rod 6, further includes at least one coupled screw rod 8 that is offset from the location directly above the resonant rod 6. The coupled screw rod 8 can also adjust the frequency by extending to different depths beneath the cover plate 2 and can also generate debris between the helical positioning threads. Therefore, the part of the coupled screw rod 8 that extends into the functional cavity 30 can also be equipped with the debris collector 4. The debris collector 4 of the coupled screw rod 8 can be only one part (the first component 41) or two parts (the first component 41 and the second component 42 connected with each other in the vertical direction). However, since there is no resonant rod 6 beneath the coupled screw rod 8 but rather the bottom of the functional cavity 30, which is the inner bottom surface of the box base 3, the debris collector 4 of the coupled screw rod 8 may not have a similar disc. Here, the disc refers to the round plate portion 424 in the third embodiment and the debris-blocking flat portion 425 in the fourth embodiment. Conversely, the role of the disc in the third embodiment and the fourth embodiment is more to reduce and even prevent debris from falling into the resonant rod 6. Therefore, due to the presence of the round plate portion 424 in the third embodiment and the debris-blocking flat portion 425 in the fourth embodiment, compared to the first embodiment and the second embodiment, the short-circuit phenomenon between the adjustable screw rod 1 and the resonant rod 6 caused by metal debris is reduced.

It can be seen that in the first embodiment, the first component 41 not only has the functions of guiding and blocking debris but also has the function of collecting debris; in the second embodiment and the third embodiment, the first component 41 mainly has the functions of guiding and blocking debris, with the function of collecting debris being secondary; in the fourth embodiment, the first component 41 only has the functions of guiding and blocking debris. In the second embodiment, the third embodiment, and the fourth embodiment, the second component 42 added beneath the first component 41 takes on more and more important functions of collecting debris; especially in the fourth embodiment, only the second component 42 collects debris.

In summary, the debris collector 4 is positioned on the bottom surface 202 of the cover plate 2 and corresponds to the through hole 20, used to collect debris that falls from the through hole 20 into the area beneath the cover plate 2, reducing the amount of debris falling into the functional cavity 30 beneath the cover plate 2, especially reducing and even preventing debris from falling into the resonant rod 6, thereby optimizing the frequency adjustment effect.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A radio frequency adjustment structure, comprising:
a box base;
a cover plate covering the box base to define a functional cavity between the cover plate and the box base, the cover plate comprising a top surface facing away from the functional cavity and a bottom surface facing the functional cavity for defining a vertical direction, the cover plate defining a through hole communicating the top surface with the bottom surface along the vertical direction;
an adjustable screw rod being positioned to the cover plate, penetrating through the through hole, and partially extending into the functional cavity; and
a debris collector being arranged beneath the bottom surface of the cover plate and corresponding to a location of the through hole.

2. The radio frequency adjustment structure according to claim 1, wherein the debris collector comprises a first component, the first component comprises a top annular surface extending in a horizontal direction perpendicular to the vertical direction, and the top annular surface is fixedly attached to the bottom surface of the cover plate at a location around the through hole.

3. The radio frequency adjustment structure according to claim 2, wherein the first component comprises a bottom annular surface extending in the vertical direction and an inner wall surface of the bottom annular surface is maintained in contact with an outer wall surface of the adjustable screw rod.

4. The radio frequency adjustment structure according to claim 2, wherein the first component comprises a first annular sidewall, which is bent and extended from the inner edge of the top annular surface to is defined as a bottom opening of the first component.

5. The radio frequency adjustment structure according to claim 4, further comprising a second component, wherein the second component is separately positioned below the first component to fill in the bottom opening.

6. The radio frequency adjustment structure according to claim 5, wherein the second component is partially inserted into the bottom opening.

7. The radio frequency adjustment structure according to claim 6, wherein the second component comprises a bottom bowl portion and a second annular sidewall extending upward from a top edge of the bottom bowl portion, the second annular sidewall is spaced apart from the adjustable screw rod and is maintained in close contact with the first annular sidewall.

8. The radio frequency adjustment structure according to claim 7, wherein the adjustable screw rod comprises an end portion, the bottom bowl portion wraps around the end portion, and the bottom bowl portion is secured to the end portion by welding.

9. The radio frequency adjustment structure according to claim 6, wherein the second component comprises an annular protrusion portion at a central thereof and a round plate portion extending outward from a bottom end of the annular protrusion portion, the annular protrusion portion comprises an inner annular wall, an outer annular wall, and an arc-shaped portion, a top end of the inner annular wall and a top end of the outer annular wall are connected by the arc-shaped portion, and the round plate portion is coupled to the outer annular wall.

10. The radio frequency adjustment structure according to claim 9, wherein the inner annular wall is maintained in contact with the outer wall surface of the adjustable screw rod and the outer annular wall is maintained in contact with the inner wall surface of the first annular sidewall.

11. The radio frequency adjustment structure according to claim 1, wherein the debris collector comprises a first component, the first component comprises a top annular surface and a first annular sidewall extending downward from the top annular surface, the top annular surface extends laterally and is fixedly attached to the bottom surface of the cover plate, the first annular sidewall is defined as a bottom opening of the first component.

12. The radio frequency adjustment structure according to claim 11, wherein the debris collector comprises a second component, the adjustable screw rod comprises an end portion extending downward through the bottom opening, the second component is a debris-blocking flat portion formed integrally by stamping from the end portion, and the debris-blocking flat portion is located below the bottom opening.

13. The radio frequency adjustment structure according to claim 1, wherein the through hole comprises an internal thread, the adjustable screw rod comprises an external thread, and the adjustable screw rod is adjustably and fixedly coupled to the cover plate through the cooperation of the internal thread and the external thread.

14. The radio frequency adjustment structure according to claim 1, further comprising a screw nut secured onto the cover plate, wherein the adjustable screw rod passes through the screw nut and extends into the through hole, the adjustable screw rod comprises an external thread, the screw nut comprises an internal thread, and the adjustable screw rod is adjustably and fixedly coupled to the cover plate through the cooperation of the internal thread and the external thread.

15. The radio frequency adjustment structure according to claim 1, further comprising a resonant rod, wherein the resonant rod is located in the functional cavity and secured to the box base, and the adjustable screw rod is located directly above the resonant rod.

16. A radio frequency adjustment structure, comprising:
a cover plate, the cover plate comprising a top surface and a bottom surface oppositely facing in a vertical direction, the cover plate defining a through hole communicating the top surface with the bottom surface along the vertical direction;
an adjustable screw rod being positioned to the cover plate and penetrating through the through hole by means of partially extending beyond the top surface and partially extending below the bottom surface; and
a debris collector being arranged just below the through hole and circularly attached to the cover plate.

17. The radio frequency adjustment structure according to claim 16, further comprising a box base; wherein the cover plate covers the box base to define a functional cavity between the cover plate and the box base.

18. The radio frequency adjustment structure according to claim 16, wherein the through hole comprises an internal thread, the adjustable screw rod comprises an external thread, and the adjustable screw rod is adjustably and fixedly coupled to the cover plate through the cooperation of the internal thread and the external thread.

19. The radio frequency adjustment structure according to claim 16, further comprising a screw nut secured onto the cover plate, wherein the adjustable screw rod passes through the screw nut and extends into the through hole, the adjustable screw rod comprises an external thread, the screw nut comprises an internal thread, and the adjustable screw rod is adjustably and fixedly coupled to the cover plate through the cooperation of the internal thread and the external thread.

20. The radio frequency adjustment structure according to claim 17, further comprising a resonant rod, wherein the resonant rod is located in the functional cavity and secured to the box base, and the adjustable screw rod is located directly above the resonant rod.
